(19) United States
(12) Patent Application Publication
(10) Pub. No.: US 2025/0210501 A1
(43) Pub. Date: Jun. 26, 2025

(54) SEMICONDUCTOR PACKAGE

(71) Applicant: SAMSUNG ELECTRONICS CO., LTD., SUWON-SI (KR)

(72) Inventors: Hee Woo AN, Suwon-si (KR); Heon Joo HA, Suwon-si (KR)

(21) Appl. No.: 18/968,897

(22) Filed: Dec. 4, 2024

(30) Foreign Application Priority Data
Dec. 22, 2023 (KR) 10-2023-0189915
Apr. 17, 2024 (KR) 10-2024-0051474

(51) Int. Cl. H01L 23/498

(52) U.S. Cl. CPC H01L 23/49838; H01L 23/49827

(57) ABSTRACT

A semiconductor package includes a package substrate and a first semiconductor device disposed on the package substrate, wherein the package substrate includes a pad array, wherein the pad array includes a first signal pad, a first power pad, and a second signal pad sequentially disposed adjacent to each other in a row, a first via spaced apart from the first signal pad, a second via spaced apart from the second signal pad, a first signal line which connects the first signal pad and the first via, a second signal line which connects the second signal pad and the second via, a ground plate disposed to surround the first via, the second via, the first signal line, and the second signal line, and a first ground via disposed between the first signal line and the second signal line, and connected to the ground plate.

### CROSS-REFERENCE TO RELATED APPLICATIONS

This application claims priority under 35 U.S.C. 119 from Korean Patent Application No. 10-2023-0189915, filed on Dec. 22, 2023, and Korean Patent Application No. 10-2024-0051474, filed on Apr. 17, 2024, in the Korean Intellectual Property Office, the contents of which are herein incorporated by reference in their entirety.

### BACKGROUND

### 1. Technical Field

The present disclosure relates to a semiconductor package, and more particularly to a semiconductor package including a package substrate and pad array.

### 2. Discussion of Related Art

In accordance with the development of the electronics industry and the demands of users, electronic devices are becoming smaller, lighter, and multifunctional. Semiconductor packages used in the electrical devices are also becoming smaller, lighter, and multifunctional.

The semiconductor packages may include structures such as pads, bumps, and wiring that may improve device density and integration. Noise may be generated in these dense and highly integrated semiconductor packages. For example, in a process of converting a signal from a power voltage into a ground voltage, a noise voltage may be generated by inductance of a wiring system. This noise may affect device performance.

### SUMMARY

Aspects of the present disclosure provide a semiconductor package that may reduce an inductance of a signal path and improve the performance thereof.

Aspects of the present disclosure provide a semiconductor package comprising a package substrate and a first semiconductor device disposed on the package substrate, wherein the package substrate includes a pad array electrically connecting the package substrate and the first semiconductor device, wherein the pad array includes a first signal pad, a first power pad, and a second signal pad sequentially disposed adjacent to each other in a row, a first via spaced apart from the first signal pad, a second via spaced apart from the second signal pad, a first signal line which connects the first signal pad and the first via, a second signal line which connects the second signal pad and the second via, a ground plate disposed to surround the first via, the second via, the first signal line, and the second signal line, and a first ground via disposed between the first signal line and the second signal line, and connected to the ground plate.

Aspects of the present disclosure also provide a semiconductor package comprising a package substrate and a first semiconductor device disposed on the package substrate, wherein the package substrate includes, a pad array electrically connecting the package substrate and the first semiconductor device, wherein the pad array further includes a first signal pad, a first power pad, and a second signal pad which are sequentially disposed adjacent to each other in a row, a first via spaced apart from the first signal pad, a second via spaced apart from the second signal pad, a third via spaced apart from the first power pad, a first signal line which connects the first signal pad and the first via, and extends in a first direction, a second signal line which connects the second signal pad and the second via, and extends in a second direction opposite to the first direction, a ground plate disposed to surround the first via, the second via, the third via, the first signal line, and the second signal line, and a first ground via disposed adjacent to the first power pad and at a side surface of the second signal line, and connected to the ground plate.

Aspects of the present disclosure also provide a semiconductor package comprising a package substrate including a plurality of substrate pads, a first semiconductor including a plurality of chip pads, and a plurality of bonding wires which connect the plurality of substrate pads to the plurality of chip pads, wherein the package substrate includes a pad array including a first signal pad, a first power pad, and a second signal pad which are sequentially disposed adjacent to each other in a row, a first via spaced apart from the first signal pad, a second via spaced apart from the second signal pad, a first signal line which connects the first signal pad and the first via, a second signal line which connects the second signal pad and the second via, a ground plate which surrounds the first via, the second via, the first signal line and the second signal line, and a first ground via which is disposed between the first signal line and the second signal line, and connected to the ground plate.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail illustrative embodiments thereof with reference to the attached drawings, in which:

FIG. 1 is a cross-sectional view of a semiconductor package according to some embodiments of the present disclosure.

FIG. 2 is a top view of the semiconductor device disposed in a semiconductor package according to some embodiments of the present disclosure.

FIG. 3 is a cross-sectional plan view taken along line L1 of FIG. 1 according to some embodiments of the present disclosure.

FIG. 4 is a cross-sectional plan view taken along line L2 of FIG. 1 according to some embodiments of the present disclosure.

FIG. 5 is an enlarged view of a region A of FIG. 1 to show paths along which the signals of the semiconductor device according to some embodiments of the present disclosure are transferred.

FIG. 6 is a block diagram for explaining an electronic device including a semiconductor package according to some embodiments of the present disclosure.

FIG. 7 is a cross-sectional plan view taken along line L1 of FIG. 1 according to some embodiments of the present disclosure.

FIG. 8 is a cross-sectional view of a semiconductor package according to another embodiment of the present disclosure.

FIG. 9 is a top view of a semiconductor device disposed on the semiconductor package according to another embodiment of the present disclosure.

FIG. 10 is a cross-sectional plan view taken along line L1 of FIG. 8 according to some embodiments of the present disclosure.

FIG. 11 is a cross-sectional plan view taken along line L2 of FIG. 8 according to some embodiments of the present disclosure.

### DETAILED DESCRIPTION

Embodiments of the present disclosure will now be described more fully hereinafter with reference to the accompanying drawings. Embodiments may, however, be provided in different forms and should not be construed as limiting. The same reference numbers indicate the same components throughout the present disclosure. In the accompanying figures, the thickness of layers and regions may be exaggerated for clarity.

Although terms such as “first” and “second” may be used to describe various elements or components in the present specification, these elements or components are not limited by these terms. These terms may be used to distinguish an element or component from other elements or components. Therefore, a “first” element or component referred to below may be a second element or component within the technical idea of the present disclosure.

In the present disclosure, an instance of a labeled element or component may be referred to as “not specifically labeled” to indicate that the element or component is substantially similar to the labeled element or component. The instance of the labeled clement or component “not specifically labeled” will be clear from the present disclosure and the drawings. A specific label may be omitted from the drawing for clarity, for example, where inclusion of an additional label may crowd the drawing.

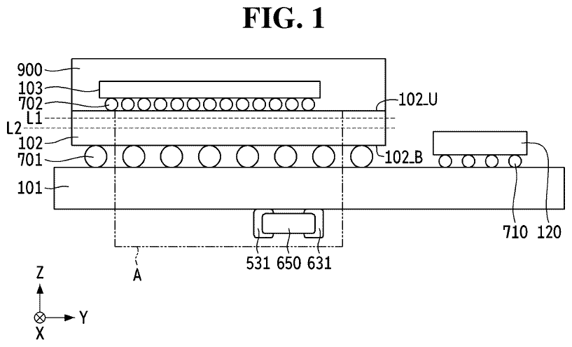

FIG. 1 is a cross-sectional view of a semiconductor package according to some embodiments of the present disclosure.

Referring to FIG. 1, the semiconductor package according to some embodiments of the present disclosure may include a first package substrate 101, a second package substrate 102, a logic chip 120, a semiconductor device 103, a multilayer ceramic capacitor (MLCC) 650, and an encapsulant 900.

The first package substrate 101 may be an external device. For example, the first package substrate 101 may be a mother board. For example, the first package substrate 101 may be a printed circuit board (PCB)) or a ceramic PCB.

A first connection terminal 701 may electrically connect the first package substrate 101 and the second package substrate 102. An electrical signal may be communicated between the first package substrate 101 and the second package substrate 102 through the first connection terminal 701. The first connection terminal 701 may include, for example, a solder ball or a solder bump.

The second package substrate 102 may be a wiring structure of the semiconductor package. For example, the second package substrate 102 may be a PCB or a ceramic PCB. Alternatively, the second package substrate 102 may be a wiring structure for a wafer level package (WLP).

The second package substrate 102 may be disposed on the first package substrate 101. For example, the second package substrate 102 may be flip-chip bonded onto the first package substrate 101. The second package substrate 102 may include an upper side 102_U and a lower side 102_B that are disposed opposite to each other. The first connection terminal 701 may be disposed on the lower side 102_B of the second package substrate 102.

The semiconductor device 103 may be disposed on the second package substrate 102. For example, the semiconductor device 103 may be flip-chip bonded onto the second package substrate 102. A second connection terminal 702 may be disposed on the upper side 102_U of the second package substrate 102. The second connection terminal 702 may electrically connect the second package substrate 102 and the semiconductor device 103. For example, an electrical signal may be communicated between the second package substrate 102 and the semiconductor device 103 through the second connection terminal 702. The second connection terminal 702 may include, for example, a solder ball or a solder bump.

The semiconductor device 103 may be a semiconductor chip. For example, the semiconductor device 103 may be a volatile memory chip such as a dynamic random access memory (DRAM) or a static RAM (SRAM).

The logic chip 120 may be disposed on the first package substrate 101. For example, the logic chip 120 may be flip-chip bonded onto the first package substrate 101. The logic chip 120 may be disposed on the first package substrate 101 adjacent to the second package substrate 102. The logic chip 120 may be spaced apart from the second package substrate 102 on the first package substrate 101.

The logic chip 120 may be, but not limited to, an application processor (AP) such as a central processing unit (CPU), a graphic processing unit (GPU), a field-programmable gate array (FPGA), a digital signal processor, an encryption processor, a micro-processor, a micro-controller, or an application-specific integrated circuit (ASIC).

The logic chip connection terminal 710 may be disposed between the logic chip 120 and the first package substrate 101. The logic chip connection terminal 710 may electrically connect the logic chip 120 and the first package substrate 101. An electrical signal may be communicated between the first package substrate 101 and the logic chip 120 through the logic chip connection terminal 710. The logic chip connection terminal 710 may include, for example, a solder ball or a solder bump.

A multilayer ceramic capacitor 650 may be disposed on a lower side of the first package substrate 101 opposite the second package substrate 102 and the logic chip 120. The multilayer ceramic capacitor 650 may serve to suppress a malfunction of an integrated circuit (IC) by keeping the voltage of the semiconductor device constant, and to emit a high-frequency noise to the outside. For example, the multilayer ceramic capacitor 650 may serve to suppress a malfunction of an IC due to overvoltage or undervoltage.

Electrical currents of the first package substrate 101 and the second package substrate 102 may flow through the multilayer ceramic capacitor 650. Specifically, the multilayer ceramic capacitor 650 may electrically connect the first package substrate 101 and the second package substrate 102, and may reduce cracks between the substrate and the metal terminal under long-term thermal shock conditions, and cracks caused by vibration or mechanical shock, and may ensure the electrical reliability of the first package substrate 101 and the second package substrate 102.

A ground connection unit 531 may be disposed on a first side of the multilayer ceramic capacitor 650. A power connection unit 631 may be disposed on a second side of the multilayer ceramic capacitor 650 opposite the first side. The ground connection unit 531 may be a path of a ground voltage inside the first package substrate 101, and the power connection unit 631 may be a path of a power voltage inside the first package substrate 101.

The encapsulant 900 may be disposed on the second package substrate 102. The encapsulant 900 may cover the second package substrate 102 and the semiconductor device 103. For example, the encapsulant 900 may cover an upper side of the second package substrate 102, and may be disposed on sidewalls and an upper side of the semiconductor device 103. For example, the encapsulant 900 may encapsulate the semiconductor device 103. A portion of the encapsulant 900 may be disposed in a space between the second package substrate 102 and the semiconductor device 103. The encapsulant 900 may increase the adhesive strength between each of the components. In addition, the encapsulant 900 may maintain an outer shape of the semiconductor package, and may protect the semiconductor device 103 from external an external environment. For example, the encapsulant 900 may protect the semiconductor device 103 from physical impacts or moisture.

The encapsulant 900 may surround the semiconductor device 103. The encapsulant 900 may include, for example, at least one of a liquid-phase epoxy molding compound (EMC), a silicone resin, a polyimide, or an equivalent thereof.

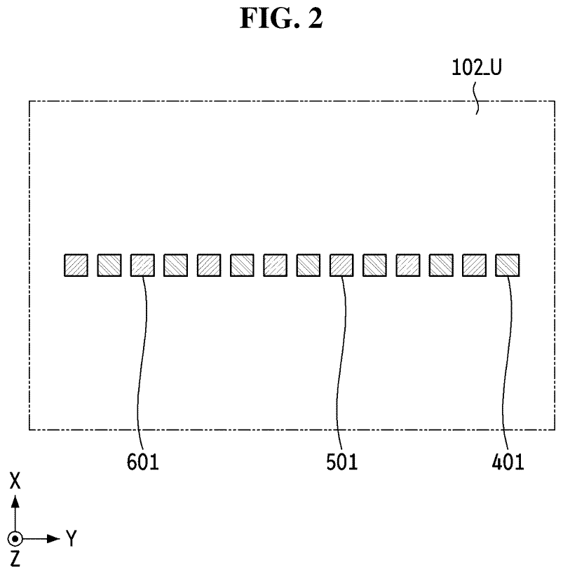

FIG. 2 is a top view of the semiconductor device disposed in a semiconductor package according to some embodiments of the present disclosure.

Referring to FIG. 2, a plurality of pads may be disposed on the upper side 102_U of the second package substrate 102. Specifically, signal pads 401, ground pads 501, and power pads 601 may be disposed on the upper side 102_U of the second package substrate 102. The signal pads 401, the ground pads 501, and the power pads 601 may be arranged in a row on the upper side 102_U of the second package substrate 102. Although FIG. 2 shows a case in which the plurality of signal pads 401, the ground pads 501, and the power pads 601 are arranged so as not to be continuous to each other, this shows merely an example case, and the present disclosure is not limited thereto.

The signal pads 401 may include, for example, DQ, DQS, DQSB, RDQS, and RDQSB pads. The DQS pad and the DQSB pad may represent a first pair of complementary signal pads. The RDQS pad and the RDQSB pad may represent a second pair of complementary signal pads. The ground pads 501 may include, for example, a VSSQ pad. The power pads 601 may include, for example, a VDDQ pad. The signal pads 401, the ground pads 501, and the power pads 601 may be connected to a plurality of second connection terminals 702 disposed on the upper side 102_U of the second package substrate 102. For example, the signal pads 401, the ground pads 501, and the power pads 601 may be connected to the plurality of second connection terminals 702 in a one-to-one manner. The plurality of signal pads 401, the ground pads 501, and the power pads 601 may include, for example, metal materials such as copper (Cu) or aluminum (Al). However, the example materials are not limiting, and the plurality of signal pads 401, the ground pads 501, and the power pads 601 may include a different material or combination of materials.

A film may be applied onto the upper side 102_U of the second package substrate 102. For example, a solder resist layer may be applied onto the upper side 102_U of the second package substrate 102.

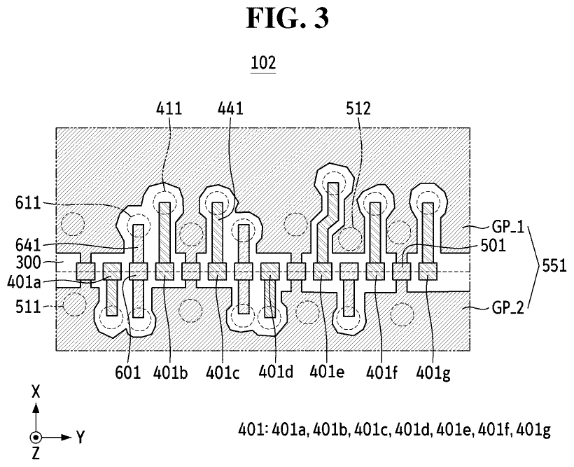

FIG. 3 is a cross-sectional plan view taken along line L1 of FIG. 1. For reference, FIG. 3 is a cross-sectional plan view showing the second package substrate 102 having an upper portion, including the upper side 102_U of the second package substrate 102 removed.

Referring to FIG. 3, a pad region 300, a plurality of signal pads 401, signal lines 441, signal vias 411, power pads 601, power lines 641, power vias 611, ground pads 501, and ground vias 511 may be disposed in the second package substrate 102.

For reference, the plurality of signal pads 401, power pads 601, and ground pads 501 may have a thickness that is thicker in a vertical direction (Z direction) than the signal line 441, the power line 641, and the ground line 541. For example, even when the cross-sectional plan view is moved lower (e.g., below line L1 in FIG. 1), due to the thickness of the plurality of signal pads 401, power pads 601, and ground pads 501 in the vertical direction (Z direction), the plurality of signal pads 401, power pads 601, and ground pads 501 may still be observed as in FIG. 3.

The plurality of signal pads 401, power pads 601, and ground pads 501 may be disposed in a pad array inside the pad region 300. For example, the plurality of signal pads 401, power pads 601, and ground pads 501 may be disposed in a row in the Y direction. The pad region 300 may include a material through which a current may not pass, and no current may pass between the signal pads 401, power pads 601, and ground pads 501. For example, the pad region 300 may include an electrically insulating material.

The ground plate 551 may include a first ground layer GP_1 and a second ground layer GP_2. The first ground layer GP_1 may be disposed on first side of the pad region 300 and the second ground layer GP_2 may be disposed on a second side of the pad region 300 disposed opposite to the first side. The ground plate 551 may surround the signal line 441, the signal via 411, the power line 641, and the power via 611, which will be described below. The ground plate 551 and the ground pad 501 may be connected.

The ground via 511 may be disposed on the ground plate 551. A plurality of ground vias may be provided including the ground via 511 and an additional ground via 512. The ground via 511 and the additional ground via 512 disposed on the ground plate 551 may be electrically connected to the ground plate 551. A pad approximately adjacent to the ground via 511 may be the ground pad 501. A pad approximately adjacent to the additional ground via 512 may be the signal pad 401 or the power pad 601.

The signal pad 401 may be a first signal pad 401a, a second signal pad 401b, a third signal pad 401c, a fourth signal pad 401d, a fifth signal pad 401e, a sixth signal pad 401f, or a seventh signal pad 401g. The signal line 441 may extend from the signal pad 401. The signal line 441 may extend in the X direction. For example, the signal line 441 may extend from the pad region in the direction to the first ground layer GP_1 or may be extend from the pad region in the direction to the second ground layer GP_2.

The signal line 441 may connect the signal pad 401 and the signal via 411 spaced apart from the signal pad 401. The signal via 411 may conduct a signal in the vertical direction (Z direction). The signal may be transferred through the signal pad 401, the signal via 411, and the signal line 441. The signal pad 401, the signal via 411, and the signal line 441 may transfer, for example, a data signal.

A power line 641 may extend from the power pad 601. The power line 641 may extend from the pad region in the direction to the first ground layer GP_1, or may extend from the pad region in the direction to the second ground layer GP_2. A power voltage may be transferred through the power line 641. The power line 641 may connect the power pad 601 and the power via 611 spaced apart from the power pad 601. The power via 611 may transfer the power voltage in the vertical direction (Z direction).

When the power line 641 is used as a reference in a process of transferring a signal through the signal line 441, an inductance may increase. If the inductance increases, a reliability of the semiconductor device may be affected.

The fifth signal pad 401e, the power pad 601 (not specifically labeled), and the sixth signal pad 401f may be sequentially disposed adjacent to each other. The signal line 441 (not specifically labeled) extending from the fifth signal pad 401e may extend from the pad region in the direction to the first ground layer GP_1. The signal line 441 (not specifically labeled) extending from the sixth signal pad 401f may extend from the pad region in the direction to the first ground layer GP_1. The power line 641 (not specifically labeled) extending from the power pad 601 (not specifically labeled) may extend from the pad region in the direction to the second ground layer GP_2. In other words, the signal line 441 (not specifically labeled) extending from the fifth signal pad 401e and the signal line 441 (not specifically labeled) extending from the sixth signal pad 401f may extend in the same direction (e.g., the X direction), and the power line 641 (not specifically labeled) extending from the power pad 601 may extend in an opposite direction (e.g., the −X direction).

The additional ground via 512 may be disposed between the signal line 441 (not specifically labeled) extending from the fifth signal pad 401e and the signal line 441 (not specifically labeled) extending from the sixth signal pad 401f. In other words, the additional ground via 512 may be surrounded by the signal line 441 (not specifically labeled) extending from the fifth signal pad 401e and the signal line 441 (not specifically labeled) extending from the sixth signal pad 401f. The additional ground via 512 may be connected to the first ground layer GP_1.

The additional ground via 512 may improve the reliability of the semiconductor device. For example, the fifth signal pad 401e or the sixth signal pad 401f approximately adjacent to the additional ground via 512 may transfer a signal and use the additional ground via 512 as a reference. In other words, the additional ground via 512 may generate a smaller loop inductance than in a case where there is no additional ground via 512, and the reliability of the semiconductor element may be improved.

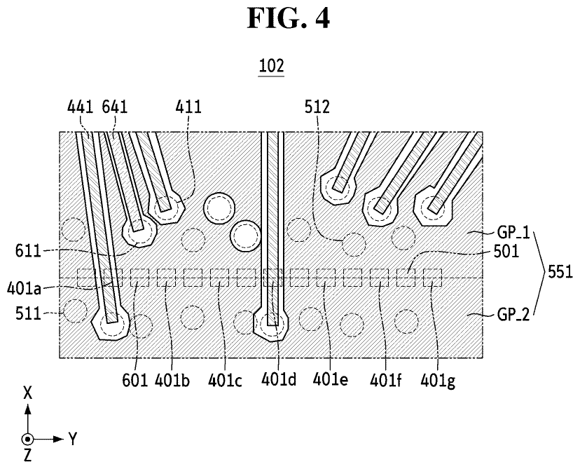

FIG. 4 is a cross-sectional plan view taken along line L2 of FIG. 1.

Referring to FIG. 4, a plurality of signal lines 441, signal vias 411, power lines 641, power vias 611, ground vias 511, additional ground vias 512, and a ground plate 551 may be disposed on a lower side of the cross-sectional layer shown in FIG. 3.

The signal line 441 may transfer a signal from the line L1 plane shown in FIG. 3 through the signal via 411. For example, the signal line 441 may conduct a signal in the Z direction. The power line 641 may transfer the power voltage from the line L1 plane shown in FIG. 3 through the power via 611. The ground via 511 and the additional ground via 512 may be connected to the ground plate 551 and may transfer the ground voltage.

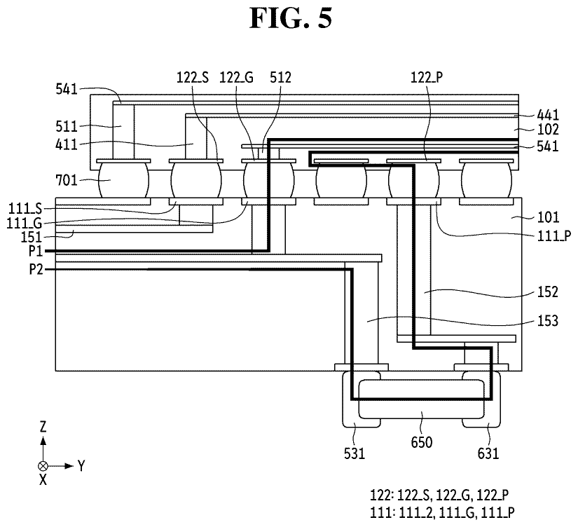

FIG. 5 is an enlarged view of a region A of FIG. 1. FIG. 5 shows paths along which the signals of the semiconductor device may be transferred according to some embodiments of the present disclosure. Referring to FIG. 5, repetitive descriptions of elements, components, or features described with reference to FIG. 1 may be omitted or simplified.

Referring to FIG. 5, the first package substrate 101 and the second package substrate 102 may be electrically connected through the first connection terminal 701. The signal, the power voltage, and the ground voltage may be transferred through a signal path 151, a power path 152, and a ground path 153 of the first package substrate 101. The signal, the power voltage, and the ground voltage may be distributed through a signal via 411, a signal line 441, a power via 611 (not shown), a power line 641 (not shown), a ground via 511, and a ground line 541 of the second package substrate 102.

A first plurality of board pads may be disposed on a surface of the first package substrate 101 and may be connected to the first connection terminals 701. The first plurality of board pads may include a signal board pad 111_S, a power board pad 111_P, and a ground board pad 111_G.

A second plurality of board pads may be disposed on a surface of the second package substrate 102 and may be connected to the first connection terminals 701. The second plurality of board pads may include a signal board pad 122_S, a power board pad 122_P, and a ground board pad 122_G.

The signal board pad 111_S of the first package substrate 101 and the signal board pad 122_S of the second package substrate 102 may be electrically connected through the first connection terminal 701 (not specifically labeled). The signal board pad 111_S and the signal board pad 122_S may transfer a signal through the first connection terminal 701 (not specifically labeled).

The power board pad 111_P of the first package substrate 101 and the power board pad 122_P of the second package substrate 102 may be electrically connected through the first connection terminal 701 (not specifically labeled). The power board pad 111_P and the power board pad 122_P may transfer a power voltage through the first connection terminal 701 (not specifically labeled).

The ground board pad 111_G of the first package substrate 101 and the ground board pad 122_G of the second package substrate 102 may be electrically connected through the first connection terminal 701 (not specifically labeled). The ground board pad 111_G and the ground board pad 122_G may transfer the ground voltage through the first connection terminal 701 (not specifically labeled).

In FIG. 3, an additional ground via 512 may be disposed on the ground board pad 122_G in substantially the same manner as disposing an additional ground via (512 of FIG. 3) and using it as a reference, as an example. As the additional ground via 512 is installed, the first path P1, which may be shorter than the second path P2, may be used as a reference. For example, the second path P2 may not be used as the reference. When the first path P1 is used as the reference, a loop inductance may be reduced as compared to a case where the second path P2 is used as the reference, and the reliability of the semiconductor element can be improved.

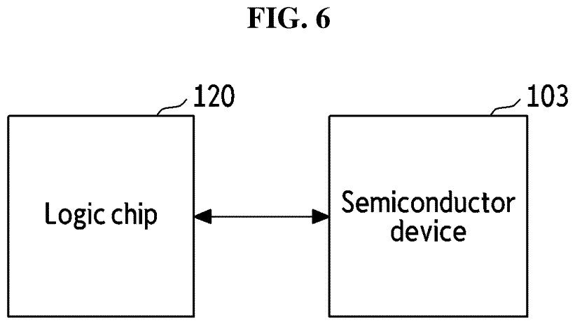

FIG. 6 is a block diagram for explaining an electronic device including a semiconductor package according to some embodiments of the present disclosure.

Referring to FIG. 6, the electronic device may include a logic chip 120 and a semiconductor device 103. The logic chip 120 may be electrically connected to the semiconductor device 103. Specifically, the logic chip 120 may provide an electrical signal to the semiconductor device 103. For example, the logic chip 120 may supply a voltage and allow a current to flow through the semiconductor device 103. The logic chip 120 may select IN/OUT portions connected to the semiconductor device 103 and allow a current to flow therethrough. The logic chip 120 may measure a current flowing through the semiconductor device 103. A user or the logic chip 120 may detect whether there is a short or an open circuit on the basis of measured current. As another example, the logic chip 120 may measure a resistance of the semiconductor device 103 to detect whether there is a short or an open circuit.

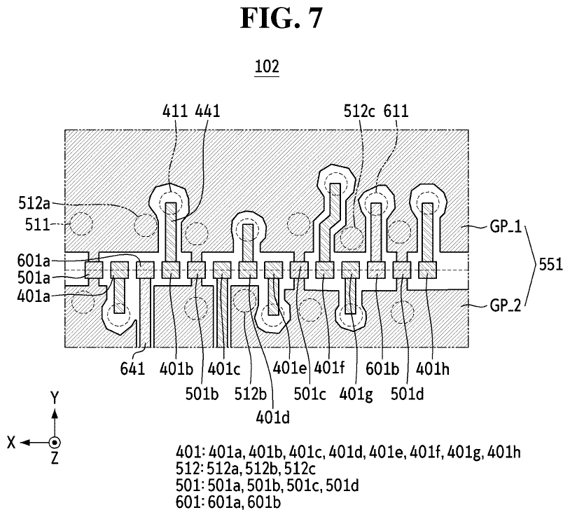

FIG. 7 is a cross-sectional plan view taken along line L1 of FIG. 1. Referring to FIG. 7 repetitive descriptions of elements, components, or features described with reference to FIG. 3 may be omitted or simplified.

Referring to FIG. 7, a plurality of signal pads 401, power pads 601, and ground pads 501 may be disposed in a pad array. For example, the plurality of signal pads 401, the power pads 601, and the ground pads 501 may be disposed in a row in the second package substrate 102.

The signal pads 401 may include a first signal pad 401a, a second signal pad 401b, a third signal pad 401c, a fourth signal pad 401d, a fifth signal pad 401e, a sixth signal pad 401f, a seventh signal pad 401g, and an eighth signal pad 401h. The ground pads 501 may include a first ground pad 501a, a second ground pad 501b, a third ground pad 501c, and a fourth ground pad 501d. The power pads 601 may include a first power pad 601a and a second power pad 601b. The additional ground vias 512 may include a first additional ground via 512a, a second additional ground via 512b, and a third additional ground via 512c.

The first ground pad 501a, the first signal pad 401a, the first power pad 601a, the second signal pad 401b, the second ground pad 501b, the third signal pad 401c, the fourth signal pad 401d, the fifth signal pad 401e, the third ground pad 501c, the sixth signal pad 401f, the seventh signal pad 401g, the second power pad 601b, the fourth ground pad 501d, and the eighth signal pad 401h may be sequentially disposed adjacent to each other in the row. However, the present disclosure is not limited to the example, and the alignment of the plurality of signal pads 401, the power pads 601, and the ground pads 501 may be different from that shown.

The first signal pad 401a, the first power pad 601a, and the second signal pad 401b may be disposed adjacent to each other in the row. The signal line 441 (not specifically labeled) extending from the first signal pad 401a may extend in the direction to the second ground layer GP_2. The power line 641 extending from the first power pad 601a may extend in the direction to the second ground layer GP_2. The signal line 441 extending from the second signal pad 401b may extend in the direction to the first ground layer GP_1. The first additional ground via 512a may be disposed adjacent to the first power pad 601a in the Y direction and at a side surface of the signal line 441 extending from second signal pad 401b.

The third signal pad 401c, the fourth signal pad 401d, and the fifth signal pad 401e may be disposed adjacent to each other in the row. The signal line 441 (not specifically labeled) extending from the third signal pad 401c may extend in the direction to the second ground layer GP_2. In some cases, a via may be omitted from the drawings. For example, the signal line 441 (not specifically labeled) extending from the third signal pad 401c may be connected to a signal via (not shown). In another example, the power line 641 extending from the first power pad 601a may be connected a power via (not shown). The signal line 441 (not specifically labeled) extending from the fourth signal pad 401d may extend in the direction to the first ground layer GP_1. The signal line 441 (not specifically labeled) extending from the fifth signal pad 401e may extend in the direction to the second ground layer GP_2. The second additional ground via 512b may be disposed between the signal line 441 (not specifically labeled) extending from the third signal pad 401c and the signal line 441 (not specifically labeled) extending from the fifth signal pad 401e.

The sixth signal pad 401f, the seventh signal pad 401g, and the second power pad 601b may be disposed adjacent to each other in the row. The signal line 441 (not specifically labeled) extending from the sixth signal pad 401f may extend in the direction to the first ground layer GP_1. The signal line 441 (not specifically labeled) extending from the seventh signal pad 401g may extend in the direction to the second ground layer GP_2. The power line 641 (not specifically labeled) extending from the second power pad 601b may extend in the direction to the first ground layer GP_1. The third additional ground via 512c may be disposed between the signal line 441 (not specifically labeled) extending from the sixth signal pad 401f and the power line 641 (not specifically labeled) extending from the second power pad 601b.

The first additional ground via 512a, the second additional ground via 512b, and the third additional ground via 512c may improve the reliability of the semiconductor device. For example, the first signal pad 401a and the second signal pad 401b approximately adjacent to the first additional ground via 512a may transfer a signal using the first additional ground via 512a as the reference. As another example, the fourth signal pad 401d approximately adjacent to the second additional ground via 512b may transfer a signal using the second additional ground via 512b as the reference. As another example, the seventh signal pad 401g approximately adjacent to the third additional ground via 512c may transfer a signal using the third additional ground via 512c as the reference.

According to an embodiment, the first additional ground via 512a, the second additional ground via 512b, and the third additional ground via 512c may generate a smaller loop inductance than in a case where the first additional ground via 512a, the second additional ground via 512b, and the third additional ground vias 512c are not present, and the reliability of the semiconductor element may be improved.

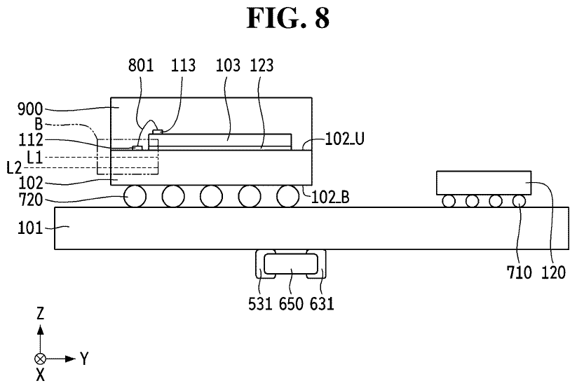

FIG. 8 is a cross-sectional view of a semiconductor package according to another embodiment of the present disclosure.

Referring to FIG. 8, the semiconductor package may include a first package substrate 101, a second package substrate 102, a semiconductor device 103, a bonding wire 801, a logic chip 120, a multilayer ceramic capacitor 650, and an encapsulant 900.

The first package substrate 101 may be an external device. For example, the first package substrate 101 may be a mother board. For example, the first package substrate 101 may be a PCB or a ceramic PCB.

A substrate connection terminal 720 may electrically connect the first package substrate 101 and the second package substrate 102. The second package substrate 102 may receive electrical signals from the first package substrate 101 through the substrate connection terminal 720. The substrate connection terminal 720 may include, for example, solder balls or solder bumps.

The second package substrate 102 may be a wiring structure for a package. For example, the second package substrate 102 may be a PCB or a ceramic PCB. Alternatively, the second package substrate 102 may be a wiring structure for a wafer-level package (WLP).

The second package substrate 102 may be disposed on the first package substrate 101. For example, the second package substrate 102 may be flip-chip bonded onto the first package substrate 101. The second package substrate 102 may include an upper side 102_U and a lower side 102_B that are disposed opposite to each other. A substrate connection terminal 720 may be disposed on the lower side 102_B of the second package substrate 102.

A plurality of substrate pads 112 may be disposed on the upper side 102_U of the second package substrate 102. The plurality of substrate pads 112 may be disposed in a row on the upper side 102_U of the second package substrate 102. The plurality of substrate pads 112 disposed on the upper side 102_U of the second package substrate 102 may be spaced apart from the semiconductor device 103. However, this is merely an example, and the present disclosure is not limited thereto. As another example, the plurality of substrate pads 112 disposed on the upper side 102_U of the second package substrate 102 may be disposed in a zigzag arrangement. The second package substrate 102 and the semiconductor device 103 may be electrically connected by the plurality of substrate pads 112. The plurality of substrate pads 112 may include, but not limited to, a metal material such as copper (Cu) or aluminum (Al).

The semiconductor device 103 may be disposed on the second package substrate 102. For example, the semiconductor device 103 may be wire-bonded to the second package substrate 102. An adhesive part 123 may be disposed on a lower side of the semiconductor device 103. The adhesive part 123 may be disposed between the semiconductor device 103 and the second package substrate 102. The adhesive part 123 may cover a surface on which the semiconductor device 103 comes into contact with the upper side 102_U of the second package substrate 102.

The adhesive part 123 may include a non-conductive film (NCF), a non-conductive paste (NCP), an insulating polymer, or an epoxy resin. However, the present disclosure is not limited thereto. The adhesive part 123 may allow the semiconductor device 103 to be attached onto the second package substrate 102.

The semiconductor device 103 may be a semiconductor chip. For example, the semiconductor device 103 may be a volatile memory chip such as a dynamic random access memory (DRAM) or a static RAM (SRAM).

A plurality of chip pads 113 may be disposed on an upper side of the semiconductor device 103. The plurality of chip pads 113 may be arranged in a row on the upper side of the semiconductor device 103. However, this is merely an example, and the present disclosure is not limited thereto. As another example, the plurality of chip pads 113 disposed on the upper side of the semiconductor device 103 may be disposed in a zigzag arrangement. The second package substrate 102 and the semiconductor device 103 may be electrically connected by the plurality of chip pads 113. The plurality of chip pads 113 may include, but not limited to, a metal material such as copper (Cu) or aluminum (Al).

The bonding wire 801 may electrically connect the semiconductor device 103 and the second package substrate 102. That is to say, the semiconductor device 103 and the second package substrate 102 may be electrically connected by the bonding wire 801. Specifically, the bonding wire 801 may electrically connect the plurality of substrate pads 112 on the second package substrate 102 and the plurality of chip pads 113 on the semiconductor device 103.

The logic chip 120 may be disposed on the first package substrate 101. In other words, the logic chip 120 may be spaced apart from the second package substrate 102, and may be disposed on the first package substrate 101. For example, the logic chip 120 may be flip-chip bonded onto the first package substrate 101.

The logic chip 120 may be, but is not limited to, an application processor (AP) such as a central processing unit (CPU), a graphic processing unit (GPU), a field-programmable gate array (FPGA), a digital signal processor, an encryption processor, a micro-processor, a micro-controller, or an application-specific IC (ASIC).

A plurality of logic chip connection terminals 710 may be disposed between the logic chip 120 and the first package substrate 101. The plurality of logic chip connection terminals 710 may electrically connect the logic chip 120 and the package substrate 100. The logic chip 120 may receive the electrical signal from the package substrate 100 through the plurality of logic chip connection terminals 710. The plurality of logic chip connection terminals 710 may include, for example, a solder ball or a solder bump.

The multilayer ceramic capacitor 650 may be provided on the lower surface of the first package substrate 101 opposite the upper surface and the second package substrate 102. The multilayer ceramic capacitor 650 may be provided on the upper surface of the first package substrate 101 on which the logic chip 120 is mounted. The multilayer ceramic capacitor 650 may suppress IC malfunctions due to overvoltage or undervoltage by keeping the voltage of the semiconductor device substantially constant, and to emit high-frequency noise to the outside.

A current may flow between the first package substrate 101 and the second package substrate 102 through the multilayer ceramic capacitor 650. Specifically, the multilayer ceramic capacitor 650 may electrically connect the first package substrate 101 and the second package substrate 102, and reduce cracks between the substrate and the metal terminal under long-term thermal shock conditions, and cracks caused by vibration or mechanical shock, and may ensure the electrical reliability of the first package substrate 101 and the second package substrate 102.

A ground connection unit 531 may be disposed on the first side of the multilayer ceramic capacitor 650. A power connection unit 631 may be disposed on the second side of the multilayer ceramic capacitor 650. The ground connection unit 531 may be a path of the ground voltage in the first package substrate 101, and the power connection unit 631 may be a path of the power voltage in the first package substrate 101.

The encapsulant 900 may be disposed on the second package substrate 102 and the semiconductor device 103. The encapsulant 900 may cover the upper sides of the second package substrate 102 and the semiconductor device 103. The encapsulant 900 may be disposed on the second package substrate 102 and the semiconductor device 103, and may increase the adhesive strength between the second package substrate 102 and the semiconductor device 103. In addition, the encapsulant 900 may maintain the outer shape of the semiconductor package and protect the semiconductor device 103 from external physical shocks or moisture.

The encapsulant 900 may surround the semiconductor device 103. The encapsulant 900 may include, for example, at least one of a liquid-phase epoxy molding compound (EMC), a silicone resin, a polyimide, or an equivalent thereof.

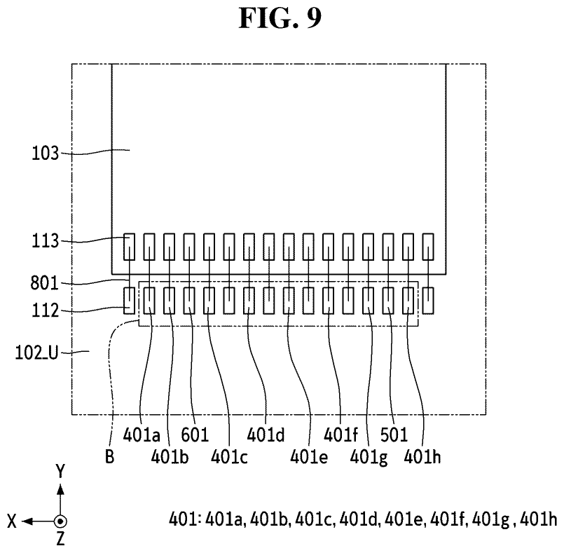

FIG. 9 is a top view of a semiconductor device mounted on the semiconductor package according to another embodiment of the present disclosure.

Referring to FIG. 9, a plurality of substrate pads 112 may be disposed in a row on the upper side 102_U of the second package substrate 102 (see FIG. 8). Specifically, the signal pad 401, the ground pad 501, and the power pad 601 may be disposed in a row on the upper side 102_U of the second package substrate 102. Although FIG. 9 shows a case in which the plurality of signal pads 401, the ground pads 501, and the power pads 601 are disposed spaced apart from each other, this is only an example, and the present disclosure is not limited thereto.

The signal pad 401 may include a first signal pad 401a, a second signal pad 401b, a third signal pad 401c, a fourth signal pad 401d, a fifth signal pad 401e, a sixth signal pad 401f, and a seventh signal pad 401g. The signal pads 401 may include, for example, DQ, DQS, DQSB, RDQS, and RDQSB pads. The DQS pad and the DQSB pad may represent a pair of complementary signal pads, and the RDQS pad and the RDQSB pad may represent a pair of complementary signal pads.

The ground pad 501 may include, for example, a VSSQ pad. The power pad 601 may include, for example, a VDDQ pad. The signal pads 401, the ground pads 501, and the power pads 601 may be connected to a plurality of chip pads 113 disposed on the upper side of the semiconductor device 103. For example, the signal pads 401, the ground pads 501, and the power pads 601 may be connected one-to-one to the plurality of chip pads 113 disposed on the upper side of the semiconductor device 103.

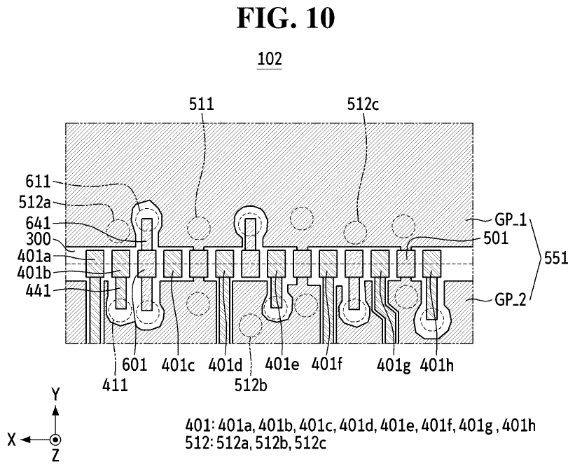

FIG. 10 is a cross-sectional plan view taken along line L1 of FIG. 8. Referring to FIG. 10, repetitive descriptions of elements, components, or features described with reference to FIG. 3 may be omitted or simplified.

Referring to FIG. 10, the pad region 300, a plurality of signal pads 401, signal lines 441, signal vias 411, power pads 601, power lines 641, power vias 611, ground pads 501, and a ground plate 551 may be disposed in the second package substrate 102. For reference, FIG. 10 is a cross-sectional plan view showing the second package substrate 102 having an upper portion, including the upper side 102_U of the second package substrate 102 removed.

The signal pads 401 may include a first signal pad 401a, a second signal pad 401b, a third signal pad 401c, a fourth signal pad 401d, a fifth signal pad 401e, a sixth signal pad 401f, a seventh signal pad 401g, and an eighth signal pad 401h. The signal lines 441 may extend from the plurality of signal pads 401. The signal lines 441 may extend in the direction to the second ground layer GP_2.

The first signal pad 401a, the second signal pad 401b, and the power pad 601 may be sequentially disposed adjacent to each other. The signal line 441 (not specifically labeled) extending from the first signal pad 401a may extend in the direction to the second ground layer GP_2. The signal line 441 extending from the second signal pad 401b may extend in the direction to the second ground layer GP_2. The power line 641 extending from the power pad 601 may extend in the direction to the first ground layer GP_1 and/or the second ground layer GP_2. In other words, the signal line 441 (not specifically labeled) extending from the first signal pad 401a and the signal line 441 extending from the second signal pad 401b may extend in the same direction (e.g., the −Y direction), and the power line 641 extending from the power pad 601 may extend in the same direction and/or in the opposite direction. The first additional ground via 512a may be disposed adjacent to the second signal pad 401b in the Y direction and to a side surface of the power line 641 extending from the power pad 601. In other words, the first additional ground via 512a may be connected to the first ground layer GP_1.

The fourth signal pad 401d, the power pad 601 (not specifically labeled), and the fifth signal pad 401e may be sequentially disposed adjacent to each other. The signal line 441 (not specifically labeled) extending from the fourth signal pad 401d may extend in the direction to the second ground layer GP_2. The power line 641 (not specifically labeled) extending from the power pad 601 (not specifically labeled) may extend in the direction to the first ground layer GP_1. The signal line 441 (not specifically labeled) extending from the fifth signal pad 401e may extend in the direction to the second ground layer GP_2. In other words, the signal line 441 (not specifically labeled) extending from the fourth signal pad 401d and the signal line 441 (not specifically labeled) extending from the fifth signal pad 401e may extend in the same direction (e.g., the −Y direction), and the power line 641 (not specifically labeled) extending from the power pad 601 (not specifically labeled), disposed between the fourth signal pad 401d and the fifth signal pad 401e, may extend in the opposite direction (e.g., the Y direction). The second additional ground via 512b may be disposed adjacent to the power pad 601 (not specifically labeled) in the −Y direction and between the signal line 441 (not specifically labeled) extending from the fourth signal pad 401d and the signal line 441 (not specifically labeled) extending from the fifth signal pad 401e. In other words, the second additional ground via 512b may be connected to the first ground layer GP_1.

The sixth signal pad 401f, the power pad 601 (not specifically labeled), and the seventh signal pad 401g may be sequentially disposed adjacent to each other. The signal line 441 (not specifically labeled) extending from the sixth signal pad 401f may extend in the direction to the second ground layer GP_2. The power line 641 (not specifically labeled) extending from the power pad 601 (not specifically labeled) may extend in the direction to the second ground layer GP_2. The signal line 441 (not specifically labeled) extending from the seventh signal pad 401g may extend in the direction to the second ground layer GP_2. In other words, the signal line 441 (not specifically labeled) extending from the sixth signal pad 401f, the signal line 441 (not specifically labeled) extending from the seventh signal pad 401g, and the power line 641 (not specifically labeled) extending from the power pad 601 (not specifically labeled) may extend in the same direction (e.g., the −Y direction). The third additional ground via 512c may be disposed at side surface of the power pad 601 (not specifically labeled) in the Y direction. In other words, the third additional ground via 512c may be connected to the first ground layer GP_1.

The first additional ground via 512a, the second additional ground via 512b, and the third additional ground via 512c may improve the reliability of the semiconductor device. For example, the second signal pad 401b approximately adjacent to the first additional ground via 512a may transfer a signal using the first additional ground via 512a as the reference. As another example, the fourth signal pad 401d and the fifth signal pad 401e both approximately adjacent to the second additional ground via 512b may each transfer a signal using the second additional ground via 512b as the reference. As another example, the sixth signal pad 401f and the seventh signal pad 401g both approximately adjacent to the third additional ground via 512c may each transfer a signal using the third additional ground via 512c as the reference.

In other words, the first additional ground via 512a, the second additional ground via 512b, and the third additional ground via 512c may generate a smaller loop inductance than in a case where the first additional ground via 512a, the second additional ground via 512b, and the third additional ground vias 512c are not present, and the reliability of the semiconductor element may be improved.

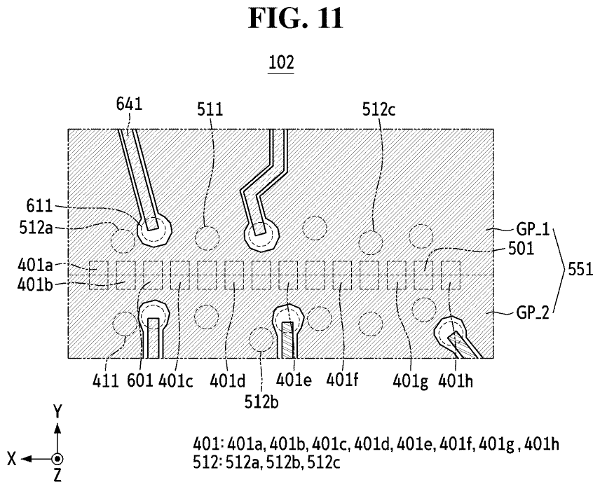

FIG. 11 is a cross-sectional plan view taken along line L2 of FIG. 8. Referring to FIG. 11, repetitive descriptions of elements, components, or features described with reference to FIG. 4 may be omitted or simplified.

Referring to FIG. 11, a plurality of signal lines 441, signal vias 411, power lines 641, power vias 611, ground vias 511, additional ground vias 512, and a ground plate 551 may be disposed on a lower side of the cross-sectional layer shown in FIG. 10. The additional ground vias 512 may include a first additional ground via 512a, a second additional ground via 512b, and a third additional ground via 512c.

The signal line 441 may transfer the signal from the L1 plane shown in FIG. 10 through the signal via 411. The power line 641 may transfer the power voltage from the L1 plane shown in FIG. 10 through the power via 611. The ground vias 511 and the additional ground vias 512 may be connected to the ground plate 551 to transfer the ground voltage.

In concluding the detailed description, those skilled in the art will appreciate that many variations and modifications may be made to the preferred embodiments without substantially departing from the principles of the present inventive concept. Therefore, the disclosed preferred embodiments of the disclosure are used in a generic and descriptive sense only and not for purposes of limitation.

What is claimed is:

1. A semiconductor package comprising:
a package substrate; and
a first semiconductor device disposed on the package substrate,
wherein the package substrate includes:
a pad array electrically connecting the package substrate and the first semiconductor device, wherein the pad array includes a first signal pad, a first power pad, and a second signal pad sequentially disposed adjacent to each other in a row;
a first via spaced apart from the first signal pad;
a second via spaced apart from the second signal pad;
a first signal line which connects the first signal pad and the first via;
a second signal line which connects the second signal pad and the second via;
a ground plate disposed to surround the first via, the second via, the first signal line, and the second signal line; and
a first ground via disposed between the first signal line and the second signal line, and connected to the ground plate.

2. The semiconductor package of claim 1,
wherein the ground plate includes a first ground plate disposed on a first side of the pad array, and a second ground plate disposed on a second side of the pad array, and
the first signal line and the second signal line extend in a direction to the first ground plate.

3. The semiconductor package of claim 2,
wherein the first ground via is connected to the first ground plate.

4. The semiconductor package of claim 2,
wherein the first semiconductor device further includes
a third via spaced apart from the first power pad; and
a power line which connects the first power pad and the third via, and extends in a direction to the second ground plate.

5. The semiconductor package of claim 2,
wherein the pad array further includes a third signal pad, a fourth signal pad, and a second power pad which are sequentially disposed adjacent to each other in a row, and
the package substrate further includes:
a third via spaced apart from the third signal pad;
a fourth via spaced apart from the fourth signal pad;
a fifth via spaced apart from the second power pad;
a third signal line which connects the third signal pad and the third via, and extends in a direction to the first ground plate;
a fourth signal line which connects the fourth signal pad and the fourth via, and extends in a direction to the second ground plate;
a power line which connects the second power pad and the fifth via, and extends in the direction to the first ground plate; and
a second ground via which is disposed between the third signal line and the power line, and connected to the first ground plate.

6. The semiconductor package of claim 2,
wherein the pad array further includes a third signal pad, a fourth signal pad, and a fifth signal pad which are sequentially disposed adjacent to each other in a row,
the package substrate further includes:
a third via spaced apart from the third signal pad;
a fourth via spaced apart from the fourth signal pad;
a fifth via spaced apart from the fifth signal pad;
a third signal line which connects the third signal pad and the third via, and extends in the direction to the first ground plate;
a fourth signal line which connects the fourth signal pad and the fourth via, and extends in the direction to the second ground plate;
a fifth signal line which connects the fifth signal pad and the fifth via, and extends in the direction to the first ground plate; and
a second ground via which is disposed between the third signal line and the fifth signal line, and connected to the first ground plate.

7. The semiconductor package of claim 1, further comprising:
a second semiconductor device installed on the first semiconductor device.

8. The semiconductor package of claim 1, wherein the first semiconductor device is flip-chip mounted on the package substrate.

9. The semiconductor package of claim 1,
wherein the package substrate further includes:
a third via disposed on the ground plate and spaced apart from the first power pad; and
a power line which connects the first power pad and the third via,
wherein the first signal line and the second signal line extend in a first direction, and the power line extends in a second direction opposite to the first direction.

10. A semiconductor package comprising:
a package substrate; and
a first semiconductor device disposed on the package substrate,
wherein the package substrate includes:
a pad array electrically connecting the package substrate and the first semiconductor device, wherein the pad array further includes a first signal pad, a first power pad, and a second signal pad which are sequentially disposed adjacent to each other in a row;
a first via spaced apart from the first signal pad;
a second via spaced apart from the second signal pad;
a third via spaced apart from the first power pad;
a first signal line which connects the first signal pad and the first via, and extends in a first direction;
a second signal line which connects the second signal pad and the second via, and extends in a second direction opposite to the first direction;
a ground plate disposed to surround the first via, the second via, the third via, the first signal line, and the second signal line; and
a first ground via disposed adjacent to the first power pad and at a side surface of the second signal line, and connected to the ground plate.

11. The semiconductor package of claim 10,
wherein the pad array further includes a third signal pad, a fourth signal pad, and a fifth signal pad sequentially disposed adjacent to each other in a row,
wherein the package substrate further includes:
a third via spaced apart from the third signal pad;
a fourth via spaced apart from the fourth signal pad;
a fifth via spaced apart from the fifth signal pad;
a third signal line which connects the third signal pad and the third via, and extends in a first direction;
a fourth signal line which connects the fourth signal pad and the fourth via, and extends in the second direction;
a fifth signal line which connects the fifth signal pad and the fifth via, and extends in the first direction; and
a second ground via disposed between the third signal line and the fifth signal line, and connected to the ground plate.

12. The semiconductor package of claim 10,
wherein the pad array further includes a third signal pad, a fourth signal pad, and a second power pad which are sequentially disposed adjacent to each other in a row, and
wherein the package substrate further includes:
a third via spaced apart from the third signal pad;
a fourth via spaced apart from the fourth signal pad;
a fifth via spaced apart from the second power pad;
a third signal line which connects the third signal pad and the third via, and extends in a first direction;
a fourth signal line which connects the fourth signal pad and the fourth via and extends in the second direction;
a power line which connects the second power pad and the fifth via, and extends in the first direction; and
a second ground via disposed between the third signal line and the power line, and connected to the ground plate.

13. A semiconductor package comprising:
a package substrate including a plurality of substrate pads;
a first semiconductor device including a plurality of chip pads; and
a plurality of bonding wires which connect the plurality of substrate pads to the plurality of chip pads,
wherein the package substrate includes:
a pad array including a first signal pad, a first power pad, and a second signal pad which are sequentially disposed adjacent to each other in a row;
a first via spaced apart from the first signal pad;
a second via spaced apart from the second signal pad;
a first signal line which connects the first signal pad and the first via;
a second signal line which connects the second signal pad and the second via;
a ground plate which surrounds the first via, the second via, the first signal line and the second signal line; and
a first ground via which is disposed between the first signal line and the second signal line, and connected to the ground plate.

14. The semiconductor package of claim 13,
wherein the package substrate further includes a third via spaced apart from the first power pad, and a power line which connects the first power pad and the third via, and
the first signal line and the second signal line extend in the same direction.

15. The semiconductor package of claim 13,
wherein the ground plate includes a first ground plate disposed on a first side of the pad array, a second ground plate disposed on a second side of the pad array, and
the first signal line and the second signal line extend in a direction to the second ground plate.

16. The semiconductor package of claim 15,
wherein the first ground plate is closer to the first semiconductor device than the second ground plate.

17. The semiconductor package of claim 16,
wherein the pad array further includes a third signal pad, a second power pad, and a fourth signal pad sequentially disposed adjacent to each other in the row, and
the package substrate includes:
a third via spaced apart from the third signal pad;
a fourth via spaced apart from the fourth signal pad;
a fifth via spaced apart from the second power pad;
a third signal line which connects the third signal pad and the third via, and extends in the direction to the second ground plate;
a fourth signal line which connects the fourth signal pad and the fourth via, and extends in the direction to the second ground plate;
a first power line which connects the second power pad and the fifth via, and extends in the direction to the second ground plate; and
a second ground via disposed adjacent to the second power pad, and connected to the first ground plate.

18. The semiconductor package of claim 13,
wherein the pad array further includes a third signal pad, a fourth signal pad, and a second power pad which are sequentially disposed adjacent to each other in a row, and
the package substrate further includes:
a third via spaced apart from the third signal pad;
a fourth via spaced apart from the fourth signal pad;
a fifth via spaced apart from the second power pad;
a third signal line which connects the third signal pad and the third via, and extends from the pad array away from the semiconductor device;
a fourth signal line which connects the fourth signal pad and the fourth via, and extends from the pad array away from the semiconductor device;
a first power line which connects the second power pad and the fifth via, and extends from the pad array toward the semiconductor device; and
a second ground via disposed adjacent to the fourth signal pad and at a side surface of the first power line.

19. The semiconductor package of claim 13,
wherein the pad array further includes a third signal pad, a second power pad, and a fourth signal pad which are sequentially disposed adjacent to each other in a row, and
the package substrate further includes:
a third via spaced apart from the third signal pad;
a fourth via spaced apart from the fourth signal pad;
a fifth via spaced apart from the second power pad;
a third signal line which connects the third signal pad and the third via, and extends from the pad array away from the semiconductor device;
a fourth signal line which connects the fourth signal pad and the fourth via, and extends from the pad array away from the semiconductor device;
a power line which connects the second power pad and the fifth via, and extends from the pad array away from the semiconductor device; and
a second ground via disposed between the power line and the semiconductor device.

20. The semiconductor package of claim 13, further comprising:
a second semiconductor device disposed on the first semiconductor device.
